(19) United States
(12) Patent Application Publication
(10) Pub. No.: US 2022/0389569 A1
(43) Pub. Date: Dec. 8, 2022

(54) DEPOSITION METHOD AND DEPOSITION APPARATUS

(71) Applicant: Tokyo Electron Limited, Tokyo (JP)

(72) Inventors: Katsumasa YAMAGUCHI, Yamanashi (JP); Tsubasa YOKOI, Yamanashi (JP)

(21) Appl. No.: 17/804,373

(22) Filed: May 27, 2022

(30) Foreign Application Priority Data
Jun. 4, 2021 (JP) 2021-094460

(51) Int. Cl. C23C 16/14; H01L 21/285

(52) U.S. Cl. CPC C23C 16/14; H01L 21/28568

(57) ABSTRACT

A deposition method includes preparing a substrate having an insulating film formed thereon, forming a first molybdenum film on the insulating film by supplying a molybdenum-containing gas and a reducing gas to the substrate while the substrate is heated to a first temperature, and forming a second molybdenum film on the first molybdenum film by supplying the molybdenum-containing gas and the reducing gas to the substrate while the substrate is heated to a second temperature that is higher than the first temperature.

### CROSS-REFERENCE TO RELATED APPLICATION

The present application is based on and claims priority to Japanese Priority Application No. 2021-094460 filed on Jun. 4, 2021, the entire contents of which are hereby incorporated herein by reference.

### BACKGROUND OF THE INVENTION

### 1. Field of the Invention

The present disclosure relates to a deposition method and a deposition apparatus.

### 2. Description of the Related Art

In order to form a wiring pattern on a surface of a semiconductor wafer, or in order to fill recesses such as recesses between wirings and recesses for contacts, a thin film is formed by depositing a metal or a metal compound.

### SUMMARY OF THE INVENTION

A deposition method according to an aspect of the present disclosure includes preparing a substrate having an insulating film formed thereon, forming a first molybdenum film on the insulating film by supplying a molybdenum-containing gas and a reducing gas to the substrate while the substrate is heated to a first temperature, and forming a second molybdenum film on the first molybdenum film by supplying the molybdenum-containing gas and the reducing gas to the substrate while the substrate is heated to a second temperature that is higher than the first temperature.

### BRIEF DESCRIPTION OF THE DRAWINGS

FIG. 1 is a flowchart illustrating an example of a deposition method of the embodiment;

FIGS. 2A to 2C are cross-sectional views illustrating an example of steps of the deposition method of the embodiment;

FIG. 3 is a drawing illustrating an example of a deposition apparatus for performing the deposition method according to the embodiment;

FIG. 4 is a graph illustrating a measurement result of film oxygen concentrations of molybdenum films;

FIG. 5 is a graph illustrating a measurement result of resistivities of molybdenum films; and

FIG. 6 is a graph illustrating an analysis result of the amount of change of Gibbs energy of various types of reactions when molybdenum films are formed by using MoO₂Cl₂ gas and H₂ gas.

### DESCRIPTION OF THE EMBODIMENT

In order to form a wiring pattern on a surface of a semiconductor wafer, or in order to fill recesses such as recesses between wirings and recesses for contacts, a thin film is formed by depositing a metal or a metal compound. For example, Japanese Laid-open Patent Application Publication No. 2003-193233 discloses a technique for forming a tungsten film in an embedded hole formed in a surface of a semiconductor wafer by alternately providing tungsten-containing gas and reducing gas to the semiconductor wafer.

Accordingly, the present disclosure provides a technique that allows a molybdenum film to be formed on a base layer, while alleviating damage to the base layer.

Hereinafter, non-limiting exemplary embodiments of the present disclosure will be described with reference to the accompanying drawings. In all the accompanying drawings, the same or corresponding reference numerals shall be attached to the same or corresponding components and overlapping descriptions may be omitted.

[Molybdenum (Mo) Film]

A molybdenum film is a low-resistance film and can be formed using fluorine-free gas. Accordingly, it is expected to be applied to gate electrodes, contacts with the source and the drain, word lines of memory, and the like in MOSFETs.

The molybdenum film is formed by, for example, atomic layer deposition (ALD) and chemical vapor deposition (CVD). When a molybdenum film is formed by ALD or CVD on a base layer, for example, a blocking oxide film of a NAND memory, a molybdenum-containing gas such as molybdenum dichloride dioxide (MoO₂Cl₂) gas and a reducing gas such as hydrogen (H₂) gas are supplied to the base layer. At this occasion, in the processing stage of deposition, the surface of the base layer is exposed, and therefore, the surface of the base layer comes into contact with the reducing gas. Accordingly, oxygen included in the base layer is removed by the reducing gas, which may reduce the property of the base layer.

Accordingly, the present disclosure provides a technique that allows a molybdenum film to be formed on a base layer, while alleviating damage to the base layer.

[Deposition Method]

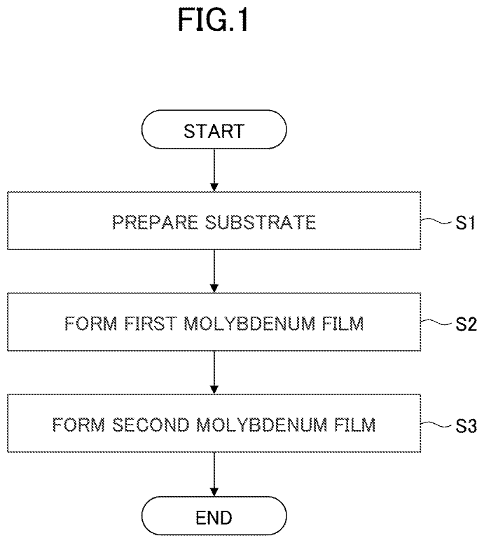

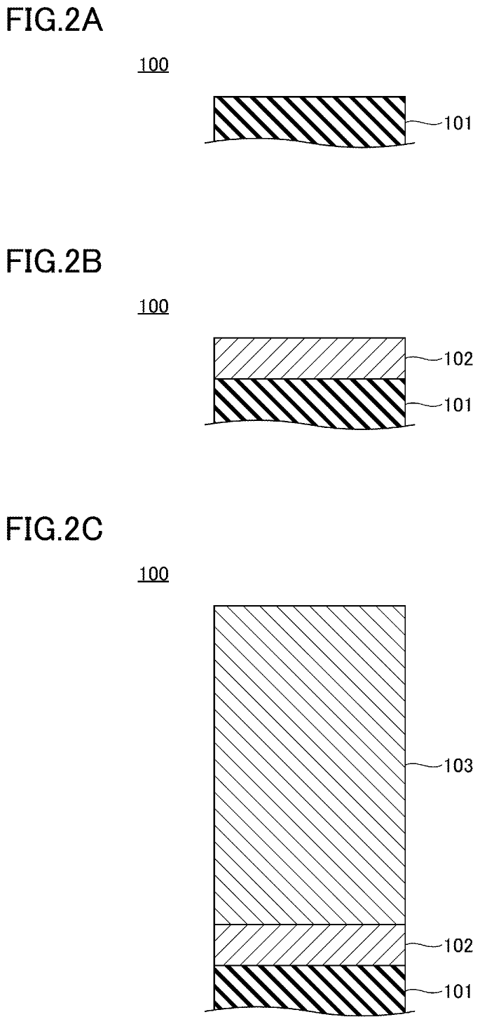

An example of a deposition method according to an embodiment is explained with reference to FIG. 1 and FIG. 2. FIG. 1 is a flowchart illustrating an example of a deposition method of the embodiment. FIGS. 2A to 2C are cross-sectional views illustrating an example of steps of the deposition method of the embodiment.

As illustrated in FIG. 1, the deposition method according to the embodiment includes forming a molybdenum film on a substrate by performing, in this order, a step S1 of preparing the substrate, a step S2 of forming a first molybdenum film, and a step S3 of forming a second molybdenum film. The molybdenum film can be used as, for example, word lines of a NAND memory.

As illustrated in FIG. 2A, the step S1 of preparing the substrate includes preparing a substrate 100 having an insulating film 101 formed thereon. The substrate 100 is, for example, a semiconductor wafer such as a silicon wafer. The insulating film 101 may be, for example, a blocking oxide film of a NAND memory, and is formed of, for example, metal oxide such as aluminum oxide (AlO).

As illustrated in FIG. 2B, the step S2 of forming the first molybdenum film includes forming a first molybdenum film 102 on the insulating film 101. The first molybdenum film 102 is a film with a higher film oxygen concentration than a second molybdenum film 103 explained later. The first molybdenum film 102 is formed on the insulating film 101 by supplying a molybdenum-containing gas and a reducing gas to the substrate 100 by, for example, ALD or CVD, while the substrate temperature is adjusted to a first temperature. The first temperature is a temperature lower than a substrate temperature of step S3 of forming the second molybdenum film 103 explained later. The molybdenum-containing gas is, for example, MoO₂Cl₂ gas. The reducing gas is, for example, H₂ gas.

As illustrated in FIG. 2C, the step S3 of forming the second molybdenum film 103 includes forming the second molybdenum film 103 on the first molybdenum film 102. The second molybdenum film 103 is a film with a lower film oxygen concentration than the first molybdenum film 102. The second molybdenum film 103 is formed on the first molybdenum film 102 by supplying the molybdenum-containing gas and the reducing gas to the substrate 100 by, for example, ALD or CVD, while the substrate temperature is adjusted to a second temperature. The second temperature is a temperature higher than the first temperature. A temperature difference between the first temperature and the second temperature is, for example, 20° C. to 300° C. The molybdenum-containing gas may be the same as the molybdenum-containing gas used in step S2 of forming the first molybdenum film, and is, for example, MoO₂Cl₂ gas. However, the molybdenum-containing gas may be different from the molybdenum-containing gas used in step S2 of forming the first molybdenum film. The reducing gas may be the same as the reducing gas used in step S2 of forming the first molybdenum film, and is, for example, H₂ gas. However, the reducing gas may be different from the reducing gas used in step S2 of forming the first molybdenum film.

As explained above, according to the deposition method of the embodiment, after the first molybdenum film 102 is formed on the insulating film 101 at the first temperature, the second molybdenum film 103 is formed on the first molybdenum film 102 at the second temperature that is higher than the first temperature. Specifically, the molybdenum film is formed at a relatively lower temperature in the initial stage when the molybdenum film is formed on the insulating film 101. Accordingly, the reducing power by the reducing gas decreases in the initial stage in which the surface of the insulating film 101 is exposed. Therefore, removing of oxygen in the insulating film 101 by the reducing gas is alleviated. As a result, the degradation of the property of the insulating film 101 caused by removed oxygen in the insulating film 101 can be alleviated.

Furthermore, in step S3 of forming the second molybdenum film 103, the molybdenum film is formed at a temperature higher than the temperature of step S2 of forming the first molybdenum film 102, and accordingly, the reducing power by the reducing gas increases, but the surface of the insulating film 101 is covered with the first molybdenum film 102. Therefore, removing of oxygen in the insulating film 101 by the reducing gas can be alleviated. As a result, the degradation of the property of the insulating film 101 caused by removed oxygen in the insulating film 101 can be alleviated.

Furthermore, the second molybdenum film 103 has a film oxygen concentration that is lower than the first molybdenum film 102, and accordingly, the second molybdenum film 103 has a lower resistivity than the first molybdenum film 102. Therefore, the first molybdenum film 102 is formed with a smaller thickness, and the second molybdenum film 103 is formed with a larger thickness, so that the low-resistance molybdenum film (i.e., the laminated film constituted by the first molybdenum film 102 and the second molybdenum film 103) can be formed.

Furthermore, according to the deposition method of the embodiment, the first molybdenum film 102 and the second molybdenum film 103 are formed by ALD or CVD using MoO₂Cl₂ gas and H₂ gas. Specifically, the molybdenum film is formed by using fluorine-free gas. Therefore, a film (for example, SiO₂ film) that is exposed when the molybdenum film is formed is less likely to be damaged by fluorine.

[Deposition Apparatus]

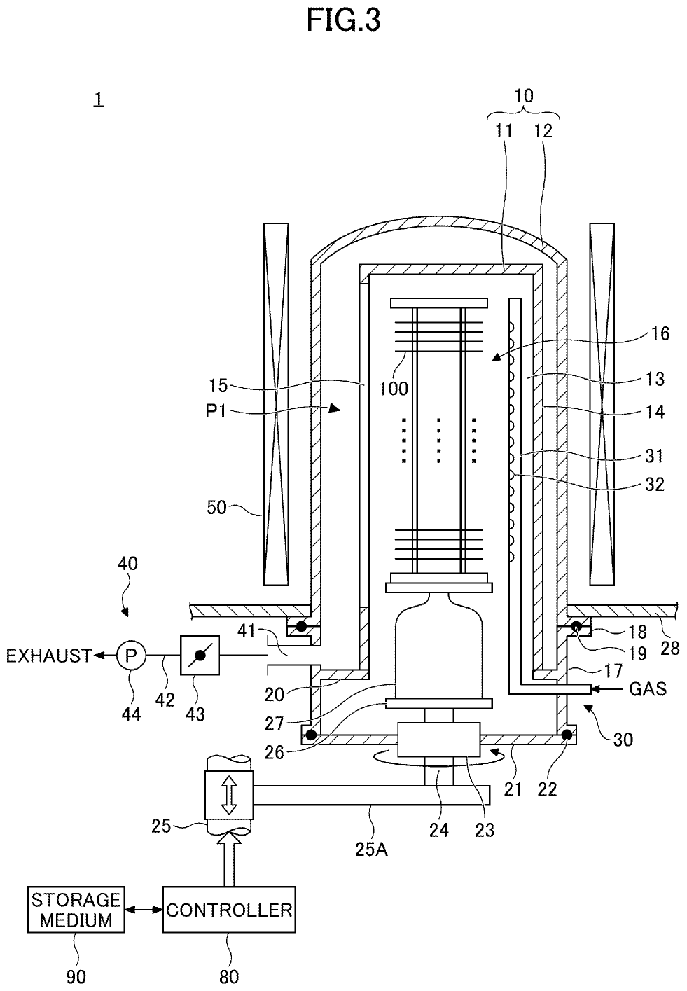

An example of a deposition apparatus that can perform the deposition method according to the embodiment is explained with reference to FIG. 3. As illustrated in FIG. 3, the deposition apparatus 1 is a batch-type apparatus that processes multiple substrates at a time.

The deposition apparatus 1 includes a process chamber 10, a gas supply 30, an exhaust 40, a heater 50, a controller 80, and the like.

The process chamber 10 is capable of decompressing the interior of the process chamber 10. The process chamber 10 accommodates substrates 100. The substrates 100 are, for example, semiconductor wafers. The process chamber 10 includes an inner tube 11, an outer tube 12, and the like. The inner tube 11 has a cylindrical shape with its bottom open and its top closed. The outer tube 12 has a cylindrical shape with its bottom open and its top closed so as to cover the outer side of the inner tube 11. The inner tube 11 and the outer tube 12 are formed of a heat-resistant material, such as quartz, arranged to be concentric to form a double tube structure.

The top of the inner tube 11 is, for example, flat. An accommodating unit 13 accommodating a gas nozzle is formed in a side wall of the inner tube 11 along the longitudinal direction of the inner tube 11. A portion of a side wall of the inner tube 11 protrudes outward to form a convex portion 14, and the inside of the convex portion 14 is formed as the accommodating unit 13.

A rectangular opening 15 is formed to face the accommodating unit 13 in a side wall on the other side of the inner tube 11 along the longitudinal direction of the inner tube 11 (the up and down direction).

The opening 15 is a gas exhaust port formed to exhaust the gas in the inner tube 11. The length of the opening 15 is formed to be the same as the length of a boat 16 or is formed to respectively extend in the up and down direction to be longer than the length of the boat 16.

The lower end of the process chamber 10 is supported by a cylindrical manifold 17 formed of, for example, stainless steel. A flange 18 is formed on the upper end of the manifold 17 and a lower end of the outer tube 12 is disposed on the flange 18 to support the lower end of the process chamber 10. A seal member 19, such as an O-ring, is interposed between the flange 18 and the lower end of the outer tube 12 to cause the inside of the outer tube 12 to be airtight.

An annular support 20 is provided on an inner wall of the upper portion of the manifold 17, and a lower end of the inner tube 11 is disposed on the support 20 to support the lower end of the process chamber 10. In an opening at the lower end of the manifold 17, a lid 21 is airtightly attached through a seal member 22, such as an O-ring, to seal the opening at the lower end of the process chamber 10, i.e., the opening in the manifold 17. The lid 21 is formed, for example, of stainless steel.

A rotating shaft 24, which rotatably supports a boat 16, is attached to the center of the lid 21 via a ferrofluidic seal 23. The lower portion of the rotating shaft 24 is rotatably supported on an arm 25A of a lifting mechanism 25 including a boat elevator.

A rotating plate 26 is provided on an upper end of the rotating shaft 24, and the boat 16 holding the substrate 100 is mounted on the rotating plate through a thermal insulation base 27 formed of quartz. Thus, the lid 21 and the boat 16 moves up and down together by the lifting mechanism 25 moving up and down, and the boat 16 is inserted and removed from the process chamber 10. The boat 16 can be accommodated in the process chamber 10 and substantially horizontally holds multiple (e.g., 50 to 150) substrates 100 with intervals in the up and down direction.

The gas supply 30 includes a gas nozzle 31. The gas nozzle 31 is, for example, quartz. The gas nozzle 31 is provided within the inner tube 11 along its longitudinal direction. A lower end portion of the gas nozzle 31 is bent in an L-shape, and is supported by the manifold 17 by penetrating the manifold 17. The gas nozzle 31 includes multiple gas holes 32 along its longitudinal direction to discharge various process gases from the multiple gas holes 32 in the horizontal direction. Multiple gas holes 32 are arranged to have intervals equal to the intervals of the substrate 100 supported in the boat 16, for example. Various process gases include a gas used in the deposition method according to the embodiment, for example, molybdenum-containing gas, reducing gas, and the like.

Although in the example of FIG. 3, a case in which the gas supply 30 includes one gas nozzle 31 has been described, the number of gas nozzles is not limited thereto. For example, the gas supply 30 may include multiple gas nozzles. In this case, various process gases may be discharged from the same gas nozzle, or may be discharged from different gas nozzles.

The exhaust 40 exhausts a gas that is exhausted from the inside of the inner tube 11 through the opening 15 and that is exhausted from a gas outlet port 41 through a space P1 between the inner tube 11 and the outer tube 12. The gas outlet port 41 is formed on a side wall of the upper portion of the manifold 17 and above the support 20. An exhaust path 42 is connected to the gas outlet port 41. A pressure adjusting valve 43 and a vacuum pump 44 are sequentially interposed in the exhaust path 42, so that the inside of the process chamber 10 can be exhausted.

The heater 50 has a cylindrical shape to cover the outer tube 12. The heater 50 is provided on, for example, a base plate 28. The heater 50 has a cylindrical shape to cover the outer tube 12. The heater 50 includes, for example, a heating element to heat the substrates 100 in the process chamber 10.

The controller 80 is configured to control operations of each unit of the deposition apparatus 1. The controller 80 may be, for example, a computer. A computer program for operating each unit of the deposition apparatus 1 is stored in a storage medium 90. The storage medium 90 may be, for example, a flexible disk, a compact disk, a hard disk, a flash memory, a DVD, or the like.

[Operations of Film Deposition Apparatus]

An example of operations of the deposition apparatus 1 that performs the deposition method according to the embodiment is explained.

First, the controller 80 controls the lifting mechanism 25 to convey the boat 16 holding the substrates 100 having the insulating films 101 formed thereon into the process chamber 10 and uses the lid 21 to airtightly close and seal the opening at the lower end of the process chamber 10.

Next, the controller 80 controls the gas supply 30, the exhaust 40, the heater 50, and the like in order to execute step S2 of forming the first molybdenum film 102. Specifically, first, the controller 80 controls the exhaust 40 to reduce the pressure in the process chamber 10 to a predetermined pressure, and controls the heater 50 to stabilize the substrate temperature at the first temperature. Next, the controller 80 controls the gas supply 30 to alternately supply the molybdenum-containing gas and the reducing gas into the process chamber 10. Accordingly, the first molybdenum film 102 is formed on the insulating film 101. In addition, purge gas may be supplied between the supply of the molybdenum-containing gas and the supply of the reducing gas.

Next, the controller 80 controls the gas supply 30, the exhaust 40, the heater 50, and the like to execute the step S3 of forming the second molybdenum film 103. Specifically, first, the controller 80 controls the exhaust 40 to reduce the pressure in the process chamber 10 to a predetermined pressure, and controls the heater 50 to stabilize the substrate temperature at the second temperature. Next, the controller 80 controls the gas supply 30 to alternately supply the molybdenum-containing gas and the reducing gas into the process chamber 10. Accordingly, the second molybdenum film 103 is formed on the first molybdenum film 102. In addition, purge gas may be supplied between the supply of the molybdenum-containing gas and the supply of the reducing gas.

Next, the controller 80 controls the lifting mechanism 25 to convey the boat 16 from the process chamber 10.

According to the above steps, the deposition apparatus 1 can form the molybdenum film (the first molybdenum film 102 and the second molybdenum film 103) on the insulating film 101 according to the deposition method according to the embodiment.

[Experiment Result]

(Film Oxygen Concentration)

Hereinafter, an experiment result for confirming a change in a film oxygen concentration of a molybdenum film when the molybdenum film is formed by changing the substrate temperature is explained.

First, while a substrate having an AlO film, i.e., an insulating film, formed thereon was heated to 530° C., a molybdenum film (a low-temperature molybdenum film) was formed on the AlO film by ALD using MoO₂Cl₂ gas, i.e., a molybdenum-containing gas, and H₂ gas, i.e., a reducing gas.

Furthermore, while the substrate having the AlO film formed thereon was heated to 580° C., a molybdenum film (a high-temperature molybdenum film) was formed on the AlO film by ALD using the MoO₂Cl₂ gas and the H₂ gas.

Next, according to the secondary ion mass spectrometry (SIMS), the film oxygen concentrations of the formed molybdenum films were measured.

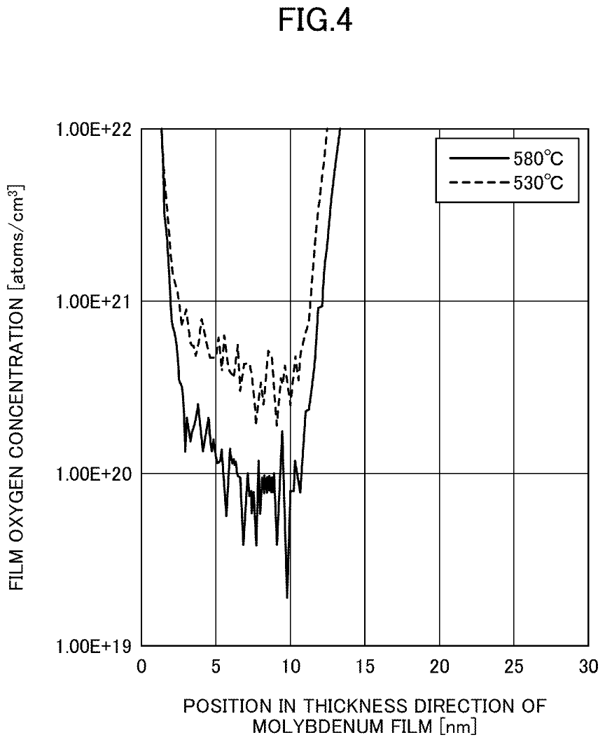

FIG. 4 is a graph illustrating a measurement result of the film oxygen concentrations of the molybdenum films. In FIG. 4, a horizontal axis indicates a position [nm] in the thickness direction of a molybdenum film, and a vertical axis indicates a film oxygen concentration [atoms/cm³] of the molybdenum film. In FIG. 4, a broken line indicates a result of the low-temperature molybdenum film (the molybdenum film formed at 530° C.), and a solid line indicates a result of the high-temperature molybdenum film (the molybdenum film formed at 580° C.)

As illustrated in FIG. 4, it is understood that the low-temperature molybdenum film had a higher film oxygen concentration than the high-temperature molybdenum film. This result indicates that when the temperature at which the molybdenum film is formed is reduced, the film oxygen concentration of the molybdenum film increases.

(Resistivity)

Hereinafter, an experiment result for confirming a change in a resistivity of a molybdenum film when the molybdenum film is formed by changing the substrate temperature is explained.

First, while a substrate having an AlO film formed thereon was heated to 530° C., a molybdenum film (a low-temperature molybdenum film) was formed on the AlO film by ALD using MoO₂Cl₂ gas and H₂ gas. The film thicknesses of the formed low-temperature molybdenum films were 8 nm and 17 nm.

Furthermore, while the substrate having the AlO film formed thereon was heated to 580° C., a molybdenum film (a high-temperature molybdenum film) was formed on the AlO film by ALD using the MoO₂Cl₂ gas and the H₂ gas. The film thicknesses of the formed high-temperature molybdenum films were 11 nm, 13 nm, 17 nm, and 21 nm.

Furthermore, the laminated molybdenum film was formed by forming, in this order, the low-temperature molybdenum film and the high-temperature molybdenum film on the substrate having the AlO film formed thereon. The total film thickness of the laminated molybdenum film was 19.5 nm.

Next, the resistivity of the formed molybdenum film was measured by a resistivity measurement device.

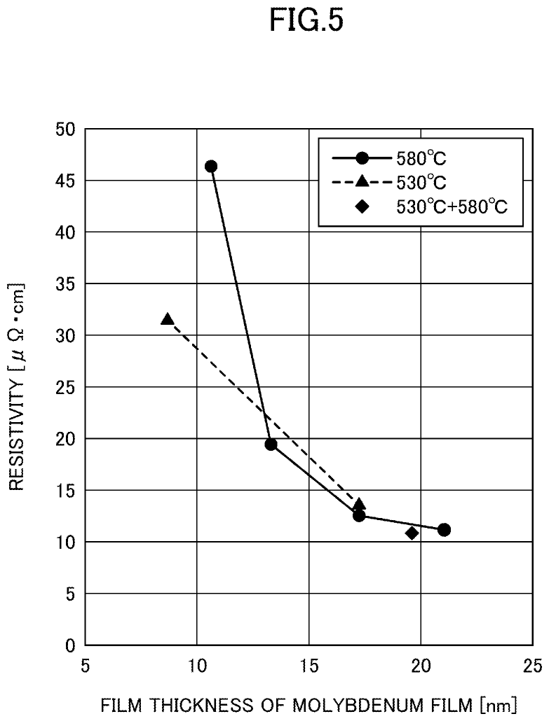

FIG. 5 is a graph illustrating a measurement result of the resistivities of the molybdenum films. In FIG. 5, a horizontal axis indicates a film thickness [nm] of a molybdenum film, and a vertical axis indicates a resistivity [μΩ·cm] of the molybdenum film. In FIG. 5, a circle mark indicates a result of the high-temperature molybdenum film (the molybdenum film formed at 580° C.), and a triangle mark indicates a result of the low-temperature molybdenum film (the molybdenum film formed at 530° C.). A diamond mark indicates a result of the laminated molybdenum film (i.e., the laminated film constituted by the molybdenum film formed at 530° C. and the molybdenum film formed at 580° C.)

As illustrated in FIG. 5, it is understood that when the film thickness of the molybdenum film is equal to or more than 13 nm, there is not a great difference in the resistivity between the low-temperature molybdenum film and the high-temperature molybdenum film. Furthermore, as illustrated in FIG. 5, it is understood that there is not a great difference in the resistivity between the laminated molybdenum film and the low-temperature molybdenum film and between the laminated molybdenum film and high-temperature molybdenum film. This result indicates that the resistivity does not decrease even if the low-temperature molybdenum film is inserted between the AlO film and the high-temperature molybdenum film.

[Simulation Result]

The amount ΔG of change of Gibbs energy of various reactions when the molybdenum film is formed by using MoO₂Cl₂ gas as the molybdenum-containing gas and using H₂ gas as the reducing gas is analyzed through simulation. The degree of progress of spontaneous reaction can be determined by calculating the amount ΔG of change of Gibbs energy. Specifically, in a case where ΔG<0, it can be determined that spontaneous reaction will progress, and as the magnitude of ΔG increases, the spontaneous reaction will progress more easily. In a case where ΔG=0, it can be determined that an equilibrium state is attained. In a case where ΔG>0, it can be determined that spontaneous reaction will not progress.

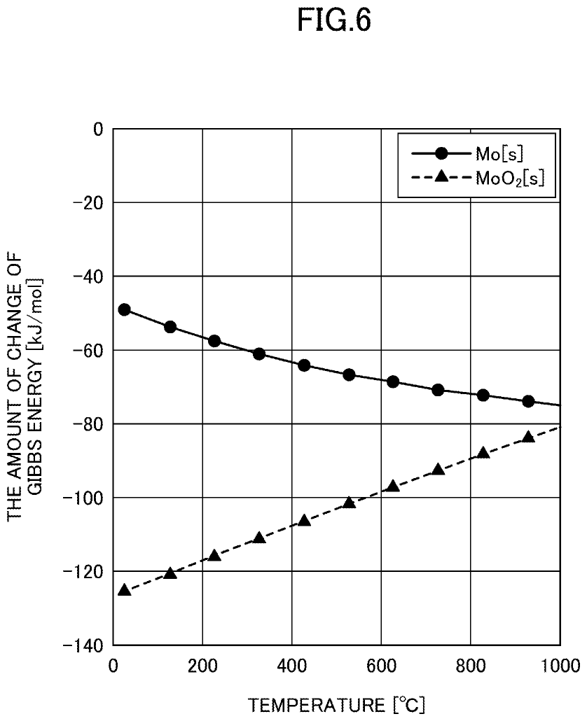

FIG. 6 is a graph illustrating an analysis result of the amount of change of Gibbs energy of various types of reactions when molybdenum films are formed by using MoO₂Cl₂ gas and H₂ gas. In FIG. 6, the horizontal axis indicates a temperature [° C.], and the vertical axis indicates the amount of change [kJ/mol] of Gibbs energy. In FIG. 6, a solid line indicates an analysis result of a reaction shown in the following Formula (1), i.e., a reaction of deposition of molybdenum (Mo). A broken line indicates an analysis result of a reaction shown in the following Formula (2), i.e., a reaction of deposition of molybdenum dioxide (MoO₂).

[Formula 1]

MoO₂Cl₂[g]+3H₂[g]→Mo[s]+2H₂O[g]+2HCl[g] (1)

[Formula 2]

MoO₂Cl₂[g]+H₂[g]→MoO₂[s]+2HCl[g] (2)

As illustrated in FIG. 6, it is understood that in a case where the temperature is 0° C. to 1000° C., the amount of change of Gibbs energy in the reaction shown in Formula (1) and the reaction shown in Formula (2) is less than zero. This result indicates that it can be understood that both of the reaction shown in Formula (1) and the reaction shown in Formula (2) will progress spontaneously.

It can be understood that in the reaction shown in Formula (1), the absolute value of the amount of change of Gibbs energy decreases in accordance with a decrease in the temperature, whereas in the reaction shown in Formula (2), the absolute value of the amount of change of Gibbs energy increases in accordance with a decrease in the temperature. This result indicates that it can be understood that when the temperature decreases, the reaction shown in Formula (2) is likely to progress. In other words, it can be understood that when the temperature decreases, the reaction of deposition of MoO₂ is more likely to progress, and a molybdenum film with a high film oxygen concentration can be formed.

The embodiment disclosed herein should be considered to be exemplary in all respects and not restrictive. The above embodiment may be omitted, substituted, or modified in various forms without departing from the appended claims and spirit thereof.

In the above-described embodiment, the deposition apparatus is assumed to be a batch-type apparatus that processes multiple substrates at a time, but the present disclosure is not limited thereto. For example, the deposition apparatus may be a single-wafer deposition apparatus that processes a single substrate at a time. Alternatively, for example, the deposition apparatus may be a semi-batch-type apparatus that causes multiple substrates on a rotation table in a process chamber to revolve with the rotation table to process the substrates by passing the substrates in order through an area to which a first gas is supplied and an area to which a second gas is supplied. Still alternatively, for example, the deposition apparatus may be a semi-batch-type apparatus that includes multiple tables in a single process chamber.

According to the present disclosure, a molybdenum film can be formed on a base layer, while alleviating damage to the base layer.

It should be understood that the embodiment of the present disclosure is exemplary and not restrictive in all respects. Further, the above-described embodiment may be omitted, replaced, or modified in various forms without departing from the subject matter described in the attached claims.

The present invention is not limited to the configurations described in the above-described embodiments in regard to, for example, combinations with other elements and the like. The embodiments of the present disclosure can be changed without departing from the subject matter described in the attached claims, and can be defined as appropriate according to the form of application thereof.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. A deposition method comprising:
preparing a substrate having an insulating film formed thereon;
forming a first molybdenum film on the insulating film by supplying a molybdenum-containing gas and a reducing gas to the substrate while the substrate is heated to a first temperature; and
forming a second molybdenum film on the first molybdenum film by supplying the molybdenum-containing gas and the reducing gas to the substrate while the substrate is heated to a second temperature that is higher than the first temperature.

2. The deposition method according to claim 1, wherein the first molybdenum film has a higher film oxygen concentration than the second molybdenum film.

3. The deposition method according to claim 1, wherein the insulating film is formed of a blocking oxide film.

4. The deposition method according to claim 1, wherein the molybdenum-containing gas is MoO₂Cl₂ gas.

5. The deposition method according to claim 1, wherein the reducing gas is H₂ gas.

6. A deposition apparatus comprising:
a process chamber configured to accommodate a substrate;
a gas supply configured to supply a process gas into the process chamber;
a heater configured to heat the substrate in the process chamber; and
a controller including a processor and a memory storing instructions that, when executed by the processor, perform operations comprising:
controlling the heater to heat the substrate having an insulating film formed thereon to a first temperature, and controlling the gas supply to supply a molybdenum-containing gas and a reducing gas into the process chamber to form a first molybdenum film on the insulating film formed on the substrate; and
controlling the heater to heat the substrate to a second temperature that is higher than the first temperature, and controlling the gas supply to supply the molybdenum-containing gas and the reducing gas into the process chamber to form a second molybdenum film on the first molybdenum film.
